(19) United States
(12) Patent Application Publication
(10) Pub. No.: US 2024/0237314 A1
(43) Pub. Date: Jul. 11, 2024

(54) SYSTEMS AND METHODS FOR COOLING OF AN ELECTRIC ENERGY STORAGE DEVICE

(71) Applicant: Ford Global Technologies, LLC, Dearborn, MI (US)

(72) Inventors: Jim Stevens, Belleville, MI (US); Jeffery Lee, Tecumseh (CA); Keith Weston, Canton, MI (US)

(21) Appl. No.: 18/153,164

(22) Filed: Jan. 11, 2023

(51) Int. Cl. H05K 7/20; B60L 58/26; H01M 10/613; H01M 10/6556; H01M 50/507

(52) U.S. Cl. CPC H05K 7/20945; B60L 58/26; H01M 10/613; H01M 10/6556; H01M 50/507; H05K 7/20872

(57) ABSTRACT

Methods and systems are provided for cooling an electric energy storage device. In some examples, a system includes an electric energy storage device comprising a plurality of battery cells, and a plurality of busbars coupled to the electric energy storage device, each busbar including a respective busbar cooling channel fluidly coupled to a cooling system including a heat exchanger, wherein coolant in the cooling system is configured to flow through each respective busbar cooling channel.

### FIELD

The present description relates generally to cooling of electric energy storage devices, and more particularly to cooling of busbars of electric energy storage devices.

### BACKGROUND/SUMMARY

Plug-in hybrid vehicles and electric vehicles may include electric energy storage devices, such as batteries, to provide electric energy to an electric machine to propel the vehicle. Despite technological achievements in battery technology, large-scale application of high-energy and high power batteries may be limited due to the cooling demands of such batteries. Accordingly, a battery thermal management system (BTMS) may be used to manage heat generation in electric energy storage devices by keeping the temperature of the energy storage device within an optimal range regardless of the load on the battery cells of the electric energy storage device.

Other attempts to address heat generation in electric energy storage devices include placing cooling plates against the electric energy storage device and/or flowing coolant along the inside of hollow busbars.

One example approach is shown by Bahrami et al. in U.S. patent Application Publication No. 2016/0190663. Therein, at least a first battery and a second battery in a battery assembly are configured to be electrically connected through their battery tabs with one or more hollow busbars forming a channel for a coolant flow. Such a system may distribute coolant flow across any surface of the electric energy storage device that is in contact with the hollow busbars, with a uniform flow rate throughout the busbar.

However, the inventors herein have recognized potential issues with such systems. For example, heat generation in electric energy storage devices may not be homogeneous. The center of the electric energy storage device may reach higher temperatures than the ends of the electric energy storage device, and significant temperature variations may occur as the size of the electric energy storage device increases. A section of the electric energy storage device that is at a higher temperature than the rest of the electric energy storage device may wear out more quickly, and therefore limit the overall life of the entire electric energy storage device.

In one example, the issues described above may be addressed by a system including an electric energy storage device comprising a plurality of battery cells, and a plurality of busbars coupled to the electric energy storage device, each busbar including a respective busbar cooling channel fluidly coupled to a cooling system including a heat exchanger, wherein coolant in the cooling system is configured to flow through each respective busbar cooling channel.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 is a schematic diagram of a first example vehicle driveline;

FIG. 2 is an example heat map of an electric energy storage device illustrating surface temperature during or after use (e.g., discharge);

FIG. 3 is an example heat map of a set of busbars illustrating surface temperature during use (e.g., discharge) of an adjacent electric energy storage device;

FIG. 4 is a schematic diagram of a busbar cooling channel;

FIG. 5 is a schematic diagram of a plurality of the busbar cooling channels each configured to cool a different busbar;

FIG. 6 is an example cooling system with a plurality of the busbar cooling channels configured to receive coolant in parallel;

FIG. 7 is an example cooling system with coolant control elements configured to control coolant flow through respective busbar cooling channels;

FIG. 8 is an example cooling system with additional cooling channels positioned adjacent to respective busbar cooling channels;

FIG. 9 is another example cooling system with additional cooling channels positioned adjacent respective busbar cooling channels;

FIG. 10 is a flow chart illustrating a method for controlling the flow of coolant through busbar cooling channels; and

FIG. 11 is a schematic diagram of a shape memory alloy actuated valve.

### DETAILED DESCRIPTION

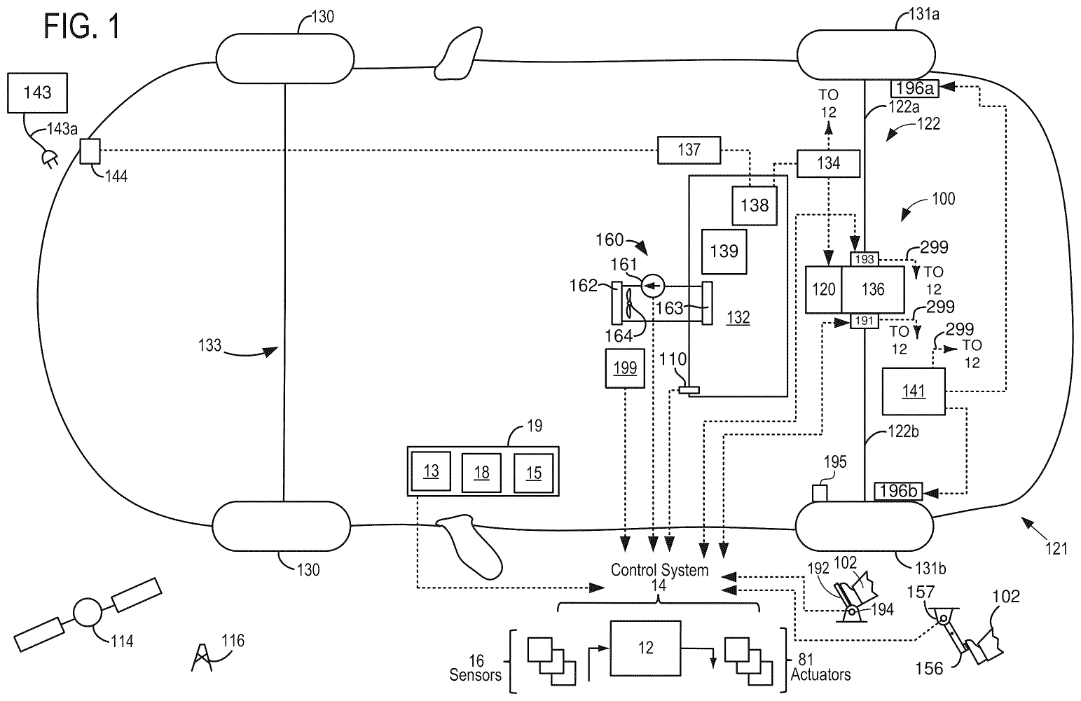

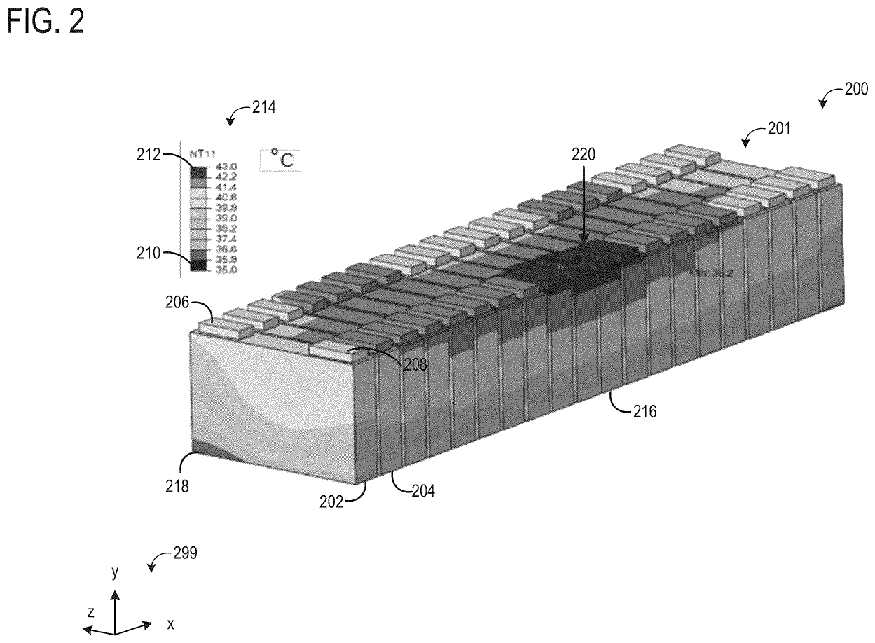

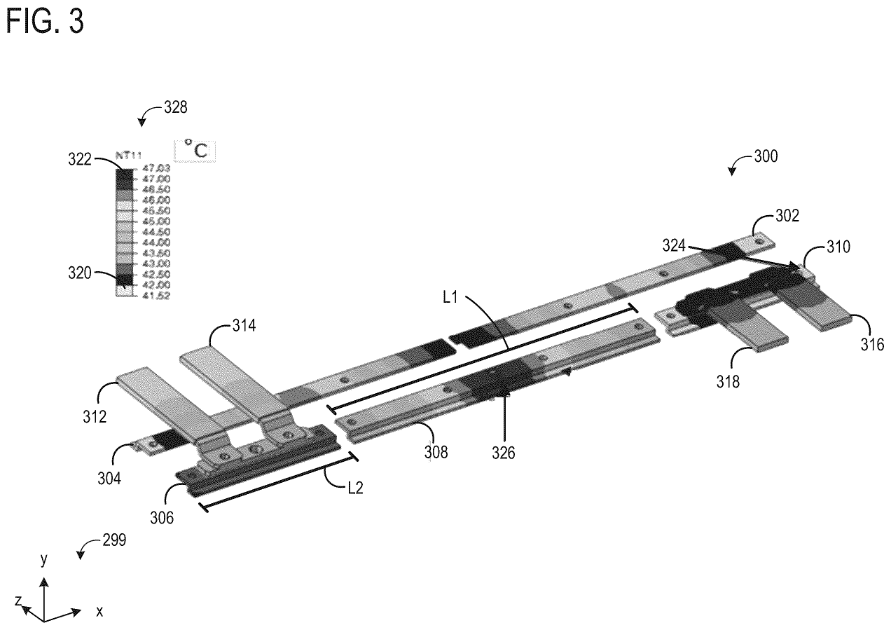

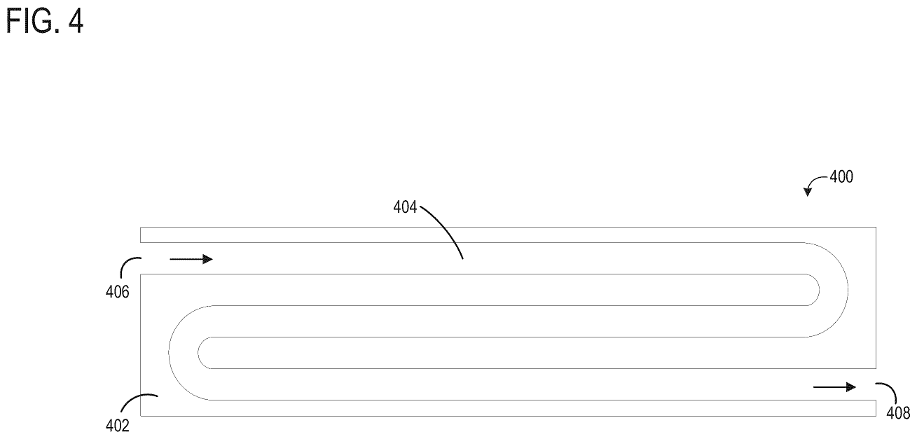

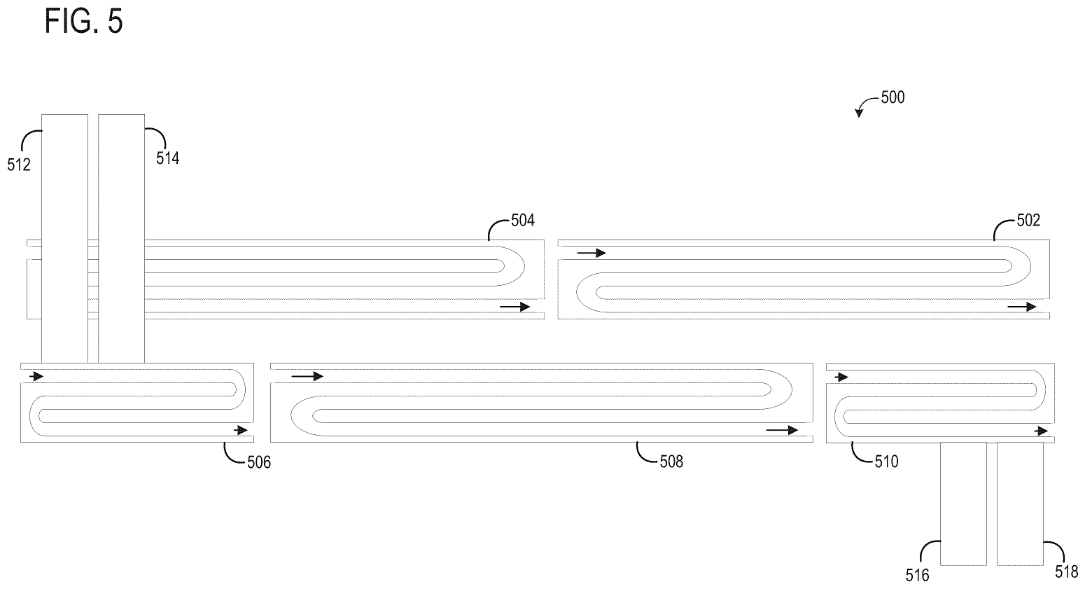

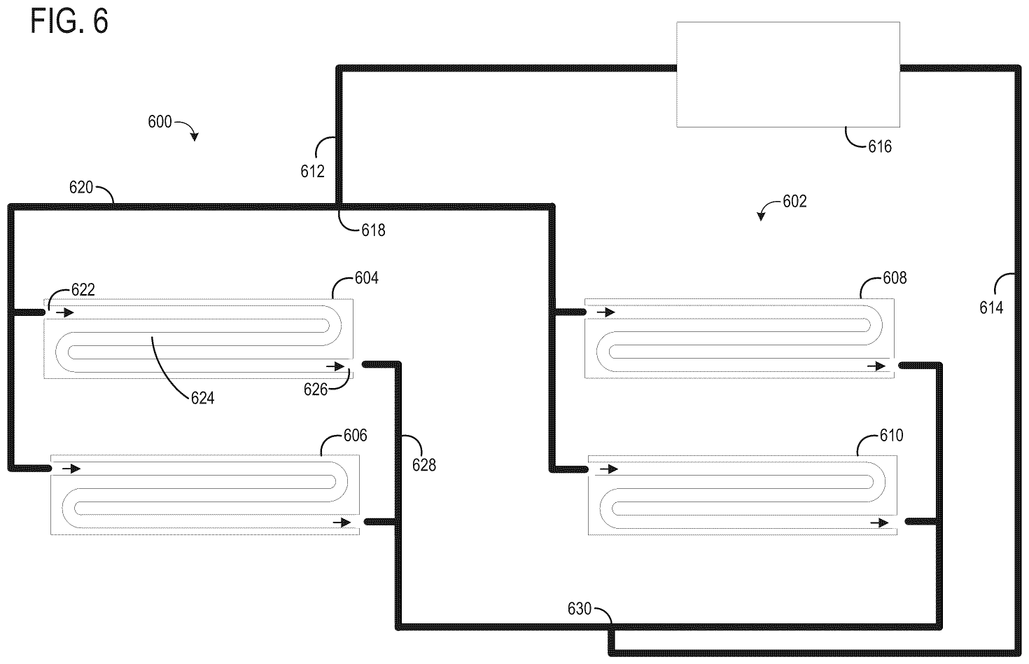

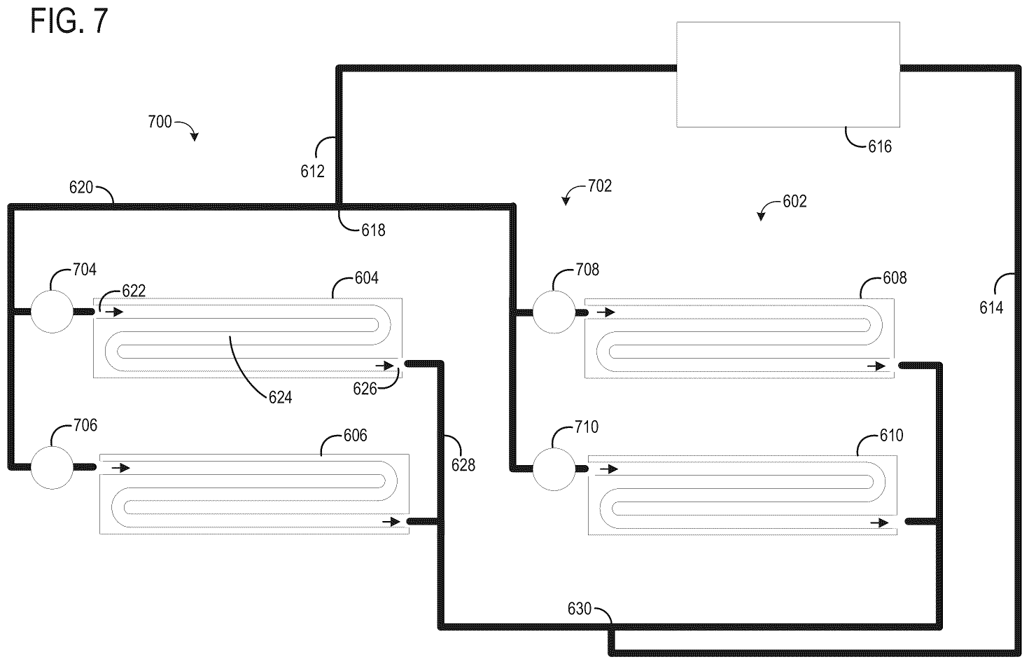

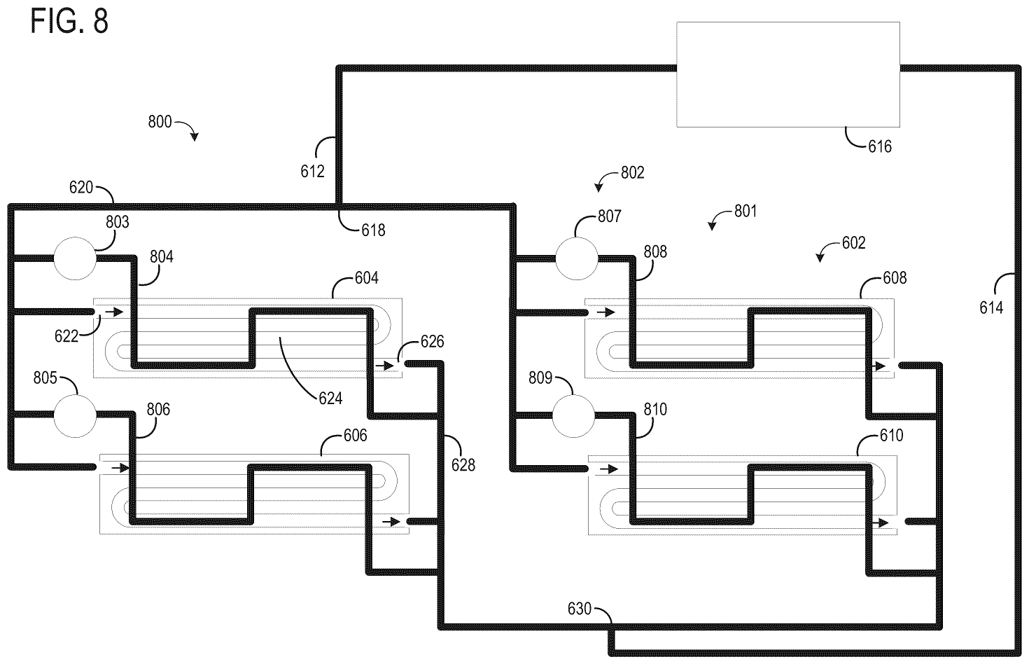

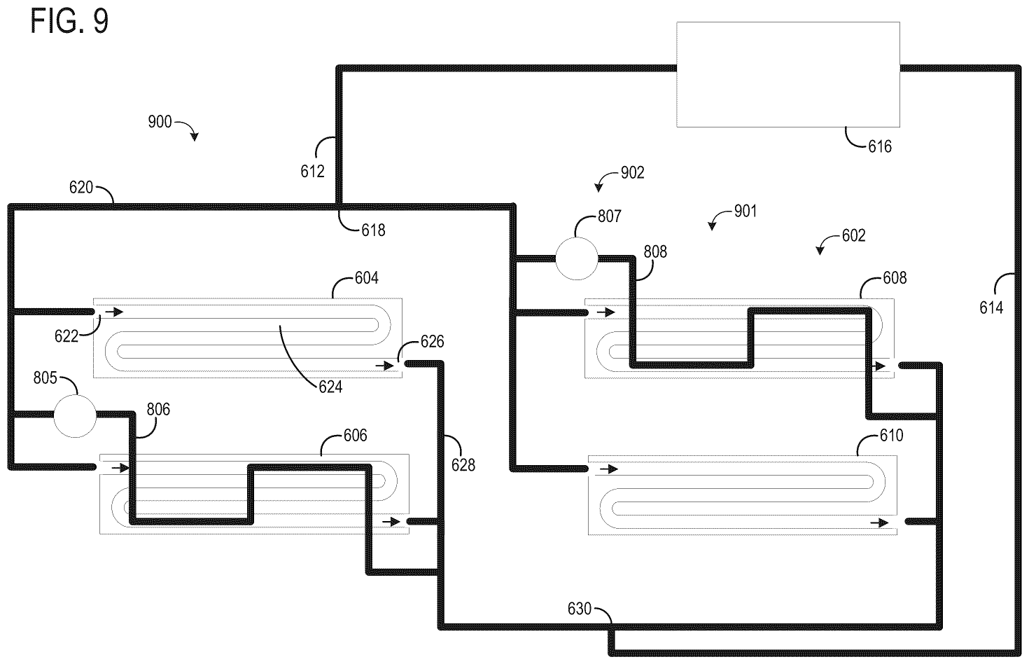

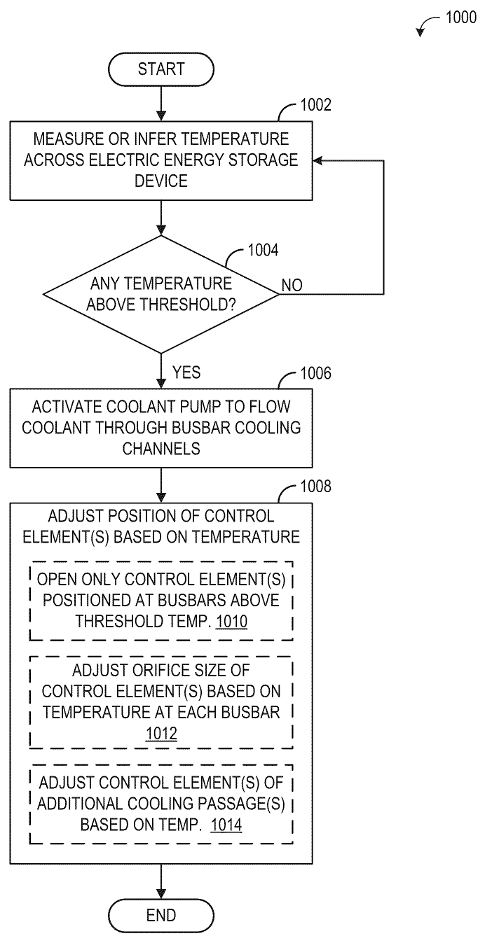

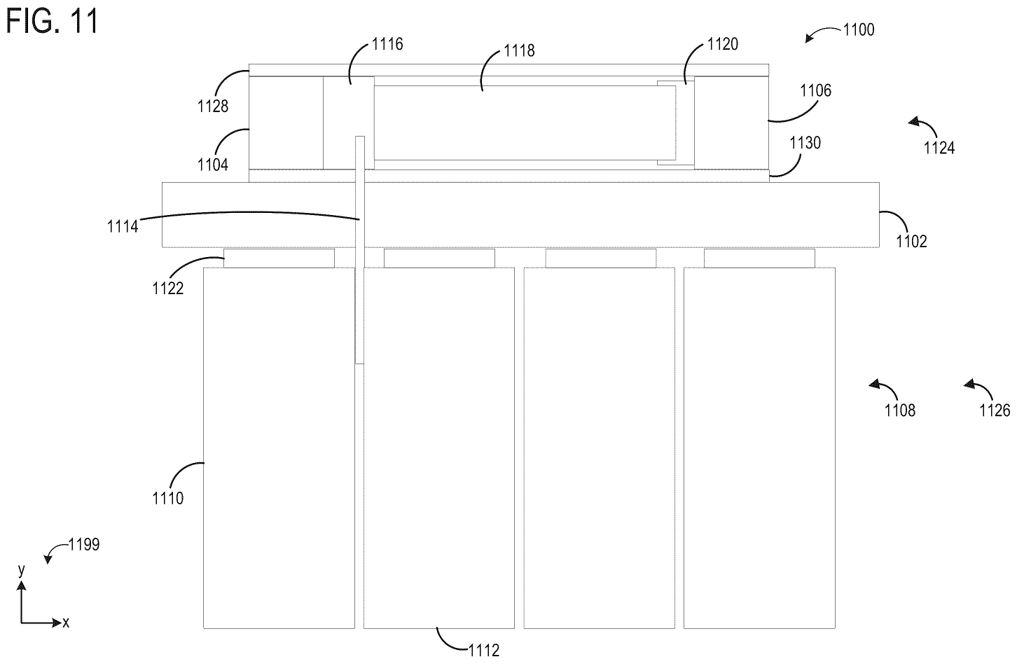

The following description relates to systems and methods for controlling cooling of an electric energy storage device, such as a battery pack comprising a plurality of battery cells. FIG. 1 shows a vehicle including an electric energy propulsion system powered by an electric energy storage device and a cooling system for cooling the electric energy storage device. As shown in FIGS. 2 and 3, the temperature across an electric energy storage device may vary. Specifically, FIG. 2 depicts temperature variation across an electric energy storage device after a high load excursion and FIG. 3 depicts temperature variation across a plurality of busbars in electrical and thermal contact with the electric energy storage device of FIG. 2. Various embodiments are disclosed herein for cooling an electric energy storage device via busbar cooling channels. FIG. 4 illustrates an example of a busbar coolant channel configured to be in thermal contact with a busbar. FIG. 5 shows a plurality of busbar cooling channels, each configured to be in thermal contact with a different respective busbar. FIGS. 6-9 show different example cooling systems that each include a plurality of busbar cooling channels and that are each configured to dissipate heat from busbars. The cooling systems shown in FIGS. 7-9 each include coolant control elements, and the cooling systems shown in FIGS. 8 and 9 each include additional coolant channels positioned adjacent to respective busbar cooling channels. In some examples, the coolant control elements may be controlled to direct coolant to busbar(s) that are determined to have a cooling demand, as illustrated by the method of FIG. 10. FIG. 11 shows a shape memory alloy actuated valve including a shape memory alloy actuator coupled to a valve flap via a hinge.

FIG. 1 illustrates an example electric vehicle propulsion system 100 for vehicle 121. The electric vehicle propulsion system 100 includes a front axle 133 and a rear axle 122. In some examples, rear axle 122 may comprise two half shafts, for example first half shaft 122a, and second half shaft 122b. The electric vehicle propulsion system 100 further includes front wheels 130 and first rear wheel 131a and second rear wheel 131b, as well as electric machine 120. Additionally, inverter 134 may be included in the propulsion system. In this example, front wheels 130 and/or first rear wheel 131a and second rear wheel 131b may be driven via electrical propulsion sources (e.g., electric machine 120). Rear axle 122 is coupled to electric machine 120, which may be referred to as a traction motor. Electric machine 120 may be the sole propulsion torque source for vehicle 121. In other examples, vehicle 121 may include one or more additional torque sources, such as an internal combustion engine. Electric machine 120 is shown coupled to differential 136, and differential 136 is part of rear axle 122.

Electric machine 120 may receive electrical power from electric energy storage device 132. Furthermore, electric machine 120 may provide a generator function to convert the vehicle's kinetic energy into electrical energy, where the electrical energy may be stored at electric energy storage device 132 for later use by the electric machine 120. A temperature of electric energy storage device 132 may be determined from output of one or more temperature sensors 110. For example, the one or more temperature sensors 110 may include a plurality of thermistors positioned at different locations across the electric energy storage device 132. An inverter 134 may convert alternating current generated by electric machine 120 to direct current for storage at the electric energy storage device 132 and vice versa. Electric energy storage device 132 may be a battery, capacitor, inductor, or other electric energy storage device.

In some examples, electric energy storage device 132 may be configured to store electrical energy that may be supplied to other electrical loads residing on-board the vehicle (other than the motor), including cabin heating and air conditioning, engine starting, headlights, cabin audio and video systems, etc. In this example configuration, vehicle 121 includes a cooling device 160 for cooling electric energy storage device 132. Cooling device 160 may extract thermal energy from electric energy storage device 132 via vapor compression, for example. In one example, cooling device 160 may be a heat pump. In other examples, cooling device 160 may be a liquid to air heat exchanger, air to air heat exchanger, or other known type of cooling device. Cooling device 160 may be controlled via control system 14 or via a local controller. Cooling device 160 may include a first heat exchanger 163 to extract thermal energy from electric energy storage device 132 and a second heat exchanger 162 to reject heat to ambient air. Cooling device 160 may also include a compressor or pump 161 for compressing a refrigerant or liquid that circulates within cooling device 160. Cooling device 160 may include a fan 164. A cooling power of cooling device 160 may be adjusted via adjusting speeds of pump 161 and fan 164, both of which may be referred to as cooling devices that are a part of cooling device 160.

Control system 14 may communicate with one or more of cooling device 160, electric energy storage device 132, electric machine 120, clutches 193 and clutches 191, brake controller 141, inverter 134, etc. Control system 14 may receive sensory feedback information from one or more of temperature sensors 110, cooling device 160, electric energy storage device 132, electric machine 120, brake controller 141, inverter 134, etc. Further, control system 14 may send control signals to one or more of cooling device 160, electric energy storage device 132, clutches 191 and clutches 193, brake controller 141, inverter 134, electric machine 120, etc., responsive to this sensory feedback. Control system 14 may receive an indication of an operator requested output of the vehicle propulsion system from a human operator 102, or an autonomous controller. For example, control system 14 may receive sensory feedback from pedal position sensor 194 which communicates with pedal 192. Pedal 192 may refer schematically to a driver demand pedal. Similarly, control system 14 may receive an indication of an operator requested vehicle braking via a human operator 102, or an autonomous controller. For example, control system 14 may receive sensory feedback from pedal position sensor 157 which communicates with brake pedal 156.

One or more wheel speed sensors 195 may be coupled to one or more wheels of the electric vehicle propulsion system 100. The wheel speed sensors 195 may detect rotational speed of each wheel. Such an example of a wheel speed sensor may include a permanent magnet type of sensor.

The electric vehicle propulsion system 100 may further include a brake system control module (BSCM). In some examples, the BSCM may comprise an anti-lock braking system, such that wheels (e.g. front wheels 130, first rear wheel 131a, second rear wheel 131b) may maintain tractive contact with the road surface according to driver inputs while braking, which may thus prevent the wheels from locking up, to prevent skidding. In some examples, the BSCM may receive input from the wheel speed sensors 195. Further, the BSCM may communicate with controller 12. The BSCM may apply right friction brakes 196a and left friction brakes 196b to apply torque to rotors (not shown) that are coupled to first half shaft 122a and second half shaft 122b to slow first rear wheel 131a and second rear wheel 131b.

Control system 14 may include a controller 12. Controller 12 is shown receiving information from a plurality of sensors 16 (various examples of which are described herein) and sending control signals to a plurality of actuators 81 (various examples of which are described herein). As one example, sensors 16 may include, wheel speed sensors 195, vehicle yaw rate sensors, vehicle longitudinal acceleration sensors, vehicle lateral acceleration sensors, steering wheel position sensors, an accelerator pedal position sensor, a brake pedal position sensor, clutch fluid pressure sensors for clutches 191 and clutches 193, temperature sensors 110, etc. In some examples, sensors associated with inverter 134, electric machine 120, clutches 191 and clutches 193, etc., may communicate information to controller 12.

Dashboard 19 may include a human machine interface 18 (HMI) configured to display information to the vehicle operator. HMI 18 may comprise, as a non-limiting example, a touchscreen or display which enables the vehicle operator to view graphical information as well as input commands. In some examples, HMI 18 may be connected wirelessly to the internet (not shown) via controller (e.g. controller 12). As such, in some examples, the vehicle operator may communicate via HMI 18 with an internet site or software application (app).

Dashboard 19 may also include a navigation system 13 that may determine a position of vehicle 121 according to data provided via a satellite network 114 and/or a cellular network 116. Navigation system 13 may also receive input from vehicle occupants. Navigation system 13 may determine a travel route between the vehicle's origin or the vehicle's present position and a destination. Navigation system 13 may also determine a distance from the vehicle's present position to the destination. Navigation system 13 may alone or in combination with control system 14 and/or HMI 18 determine driving patterns. The driving patterns may include routes and parking times for home, stores, offices, filling stations, etc. that are frequent destinations for the vehicle.

Navigation system 13 may also receive weather forecasts for times and days in the future so that navigation system and/or controller 12 may determine a future temperature at the vehicle's destination or parking location. For example, navigation system 13 may request a weather forecast data from a remote server via satellite network 114 or cellular network 116. The weather data may then be used as the ambient environmental temperature at the time the vehicle parks and at the time that the vehicle is expected to exit park.

Dashboard 19 may further include an operator interface 15 via which the vehicle operator may adjust the operating status of the vehicle. Specifically, the operator interface 15 may be configured to initiate and/or terminate operation of the vehicle driveline (e.g., inverter 134 and electric machine 120) based on an operator input.

Electric energy storage device 132 includes an electric energy storage device controller 139 and a power distribution module 138. Electric energy storage device controller 139 may provide charge balancing between energy storage elements (e.g., battery cells) and communication with other vehicle controllers (e.g., controller 12). Power distribution module 138 controls flow of power into and out of electric energy storage device 132. Electric energy storage device 132 may receive electric power via a charger 137. Charger 137 may receive electric power via stationary power grid 143 by way of plug 143a and receptacle 144.

The system of FIG. 1 shows controller 12 and brake controller 141, but the methods and systems described herein are not limited to one configuration. Rather, the system may include a single controller or it may distribute control via additional controllers. For example, the system may include a separate controllers configured in hardware and in the form of a vehicle controller, inverter 134, an electric machine controller, a braking system controller, and a vehicle stability controller. Alternatively, the system may include a single controller configured in hardware for performing the method described herein. Thus, the system described herein should not be construed as limiting.

FIG. 2 illustrates the surface temperature of an example electric energy storage device 200, such as electric energy storage device 132 of FIG. 1, during use (e.g., discharge). The heat map shown in FIG. 2 may illustrate the temperature of the electric energy storage device 200 after a high load/energy demand excursion, such as after a vehicle within which the electric energy storage device 200 is positioned is propelled at prolonged high speed. FIG. 2, as well as FIG. 3, includes a Cartesian coordinate system 299 to orient the views. The y-axis may be a vertical axis (e.g., parallel to a gravitational axis), the x-axis may be a longitudinal axis (e.g., horizontal axis), and/or the z-axis may be a lateral axis, in one example. However, the axes may have other orientations, in other examples.

The electric energy storage device 200 may be comprised of a plurality of batteries 201 (also referred to as battery cells), including at least a first battery 202 and a second battery 204. In some examples, the plurality of batteries 201 including at least the first battery 202 and the second battery 204 may each include a stack of electrochemical cells encased in an electrically inert case. In the example illustrated in FIG. 2, the plurality of batteries 201 includes twenty batteries, but it is to be appreciated that more or fewer batteries may be included without departing from the scope of this disclosure.

Each battery cell of the plurality of batteries 201 may have a set of electric tabs, such as a positive tab 206 and a negative tab 208 of the first battery 202, that extend outside of the battery core along the y-axis. Each set of electric tabs may be electrically and thermally conductive, and may be used for the purpose of electrical connection of the battery to a load (e.g., for discharging) and/or a charger (e.g., for charging).

The electric energy storage device 200 may include an outer core that houses the plurality of batteries 201, which is removed from FIG. 2 for visual clarity. The outer core may include or be in contact with a cold plate extending along a bottom surface of the outer core (e.g., extending along a z-x plane). The cold plate may have at least one internal channel carrying a fluid coolant (e.g., liquid or gas) used to transfer heat produced by the electric energy storage device 200 to a heat sink.

In some examples, the plurality of batteries 201 may be connected to one or more busbars via the respective sets of electric tabs. Each of the one or more busbars may be configured to attach to a subset of the plurality of batteries within the electric energy storage device 200 in order to provide electrical communication between the batteries. The one or more busbars may also be configured to dissipate the heat that is generated by at least one of the plurality of batteries 201.

As illustrated in FIG. 2, the temperature of the electric energy storage device 200 may not be uniform across the surfaces of the device. In the example shown in FIG. 2, the bottom surfaces (e.g., opposite of the electric tabs) of the plurality of batteries 201 may be at a lower temperature relative to the top surfaces (e.g., containing the electric tabs) of the plurality of batteries 201. The bottom surfaces of the plurality of batteries 201 may be in thermal contact with a cold plate, and therefore may dissipate more heat relative to the rest of the electric energy storage device 200. The top surfaces of the plurality of batteries 201 may generate more heat due to the charging and/or discharging that occurs through the electric tabs. The top surfaces of the plurality of batteries 201 may also be furthest from the cold plate, and therefore may dissipate less heat relative to the rest of the electric energy storage device 200.

In some examples, the electric energy storage device 200 may contain a plurality of batteries 201 structured linearly along the x-axis. In such examples, the temperature of the electric energy storage device 200 may be lowest at the batteries that comprise the terminating ends of the electric energy storage device 200 along the x-axis. The temperature of the electric energy storage device 200 may be highest at the midpoint between the terminating ends of the electric energy storage device 200 along the x-axis.

As shown in FIG. 2, a legend 214 illustrates the interpretation of the heat map of the temperature across the surface of the electric energy storage device 200 after a high load/energy demand excursion. The legend 214 shows a first temperature 210 (e.g., of 35 degrees Celsius) and a second temperature 212 (e.g., of 43 degrees Celsius) with a gradient of temperatures between the first temperature 210 and the second temperature 212. The electric energy storage device 200 may have a cold spot 218 with a temperature of approximately the first temperature 210. The cold spot 218 may be located on a portion of the bottom surface of the first battery 202 of the plurality of batteries 201. The electric energy storage device 200 may have a hot spot 220 with a temperature of approximately the second temperature 212. The hot spot 220 may be located on a portion of the top surface of an eleventh battery 216 of the plurality of batteries 201 as well as portions of the top surfaces of one or more batteries neighboring the eleventh battery 216. It is to be appreciated that the distribution of temperatures across the electric energy storage device 200 shown in FIG. 2 is exemplary and that different vehicle operating states may result in different temperature distributions than shown in FIG. 2 and/or different energy storage devices may exhibit different variations in temperature than shown in FIG. 2.

FIG. 3 illustrates surface temperatures of an example plurality of busbars 300, which may be connected to an electric energy storage device, such as the electric energy storage device of FIG. 2, during use (e.g., discharge). The heat map shown in FIG. 3 may illustrate the temperature of the plurality of busbars 300 after a high load/energy demand excursion, such as after a vehicle within which the plurality of busbars 300 is positioned is propelled at prolonged high speed. In particular, the plurality of busbars 300 may be coupled to the electric energy storage device 200 and the temperature distribution of the plurality of busbars 300 shown in FIG. 3 may be the temperatures of the plurality of busbars 300 after the same operating conditions that resulted in the temperature distribution of the electric energy storage device 200 shown in FIG. 2.

The plurality of busbars 300 may be comprised of a first busbar 302, a second busbar 304, a third busbar 306, a fourth busbar 308, and a fifth busbar 310. In other examples, the plurality of busbars 300 may be comprised of a suitable number of busbars that is less or more than five (e.g., one busbar, ten busbars, etc.). In some examples, the first busbar 302, the second busbar 304, and the fourth busbar 308, may each have a first length L1 that extends along the x-axis. The third busbar 306 and the fifth busbar 310 may each have a second length L2 that extends along the x-axis, where L2 is smaller than L1. Each busbar may have a respective longitudinal axis extending along the x-axis. In the example shown, the first busbar 302 and the second busbar 304 may be aligned along their longitudinal axes. The third busbar 306, the fourth busbar 308, and the fifth busbar 310 may have their longitudinal axes aligned along the x-axis, but with a suitable offset along the y-axis relative to the first busbar 302 and the second busbar 304. The fourth busbar 308 may be positioned in between the third busbar 306 and the fifth busbar 310 along the x-axis. The first busbar 302 and the fifth busbar 310 may each have one terminating end vertically adjacent to a terminating end of an electric energy storage device along the x-axis. The second busbar 304 and the third busbar 306 may each have one terminating end vertically adjacent to the other terminating end of the electric energy storage device along the x-axis.

While FIG. 3 shows the plurality of busbars 300 in isolation for visual clarity, it is to be appreciated that the plurality of busbars 300 may be positioned on the electric energy storage device 200 to facilitate current flow and heat dissipation of the electric energy storage device 200. When the plurality of busbars 300 are positioned on the electric energy storage device 200, the busbars may be positioned as shown in FIG. 3, such that some of the busbars, such as the first busbar 302 and the second busbar 304, may be in contact with the negative electric tabs of the plurality of batteries 201 in FIG. 2. Other busbars, such as the third busbar 306, the fourth busbar 308, and the fifth busbar 310, may be in contact with the positive electric tabs of the plurality of batteries. The third busbar 306 may have a set of connectors, such as a first connector 312 and a second connector 314, that may be electrically and thermally conductive. The fifth busbar 310 may have a set of connectors, such as a third connector 316 and a fourth connector 318, that may be electrically and thermally conductive. The first connector 312, second connector 314, third connector 316, and fourth connector 318 may be used for the purpose of electrical connection of the electric energy storage device 200 to a load (e.g., for discharging) and/or a charger (e.g., for charging).

In some examples, each busbar of the plurality of busbars 300 may be comprised of a solid material that is electrically and thermally conductive. In other examples, each busbar of the plurality of busbars 300 may be hollow with a channel for coolant flow. The coolant flow within the cooling channel or hollow busbar may be used to transfer heat produced by an adjacent electric energy storage device to a heat sink. In still further examples, explained herein, each busbar of the plurality of busbars 300 may be comprised of solid material and may include a set of cooling channels formed via over-molding of the busbar.

As illustrated in FIG. 3, the temperature of the plurality of busbars 300 may not be uniform across the plurality of busbars 300. In some examples, the temperature may be higher near the center of each of the busbars, where the center is the midpoint between the terminating ends of the busbar along the x-axis. As shown in FIG. 3, a legend 328 illustrates the interpretation of the heat map of the temperature across the surface of the plurality of busbars 300 after a high load/energy demand excursion. The legend 328 shows a first temperature 320 (e.g., of 41.5 degrees Celsius) and a second temperature 322 (e.g., of 47 degrees Celsius) with a gradient of temperatures between the first temperature 320 and the second temperature 322. The plurality of busbars 300 may have a cold spot 324 with a temperature of approximately the first temperature 320. The cold spot 324 may be located at one terminating end of the fifth busbar 310 along the x-axis. The plurality of busbars 300 may have a hot spot 326 with a temperature of approximately the second temperature 322. The hot spot 326 may be located at the midpoint between the terminating ends of the fourth busbar 308 along the x-axis. The hot spot 326 may be positioned directly above a hot spot of an electric energy storage device, such as the hot spot 220 of the electric energy storage device 200 that is illustrated in FIG. 2. In this way, the hot spot 326 may have a larger amount of heat transferred to it from an electrically and thermally connected electric energy storage device than any other point on the plurality of busbars 300.

Thus, an electric energy storage device of an electric vehicle may be comprised of a plurality of battery cells, with each battery cell including a positive tab and a negative tab, as shown in FIG. 2. Electric communication among the battery cells, one or more energy consumers, and/or one or more energy sources may be facilitated via a plurality of busbars coupled to the battery cells (and specifically to the positive or negative tabs). Various vehicle operating conditions may result in a relatively high thermal load on the electric energy storage device. Due to the configuration of the electric energy storage device (e.g., position of each positive tab and each negative tab, position of a cooling plate, number and arrangement of the battery cells), the thermal load may not be distributed evenly across the electric energy storage device, resulting in one or more regions of the electric energy storage device that may not be adequately cooled by a traditional cold plate. While the busbars may further help dissipate heat from the battery cells, the uneven temperature distribution may be observed in the busbars as well. Exposure to high temperature may degrade the performance of the electric energy storage device and may reduce the lifespan of the electric energy storage device.

Thus, as explained in more detail below, additional heat dissipation along the top of the electric energy storage device (where high temperatures are prone to occur) may be facilitated by busbar cooling channels that may be integrated in or on the busbars of the electric energy storage device to lower temperature and even out the distribution of heat. The busbar cooling channels may be additive manufactured cooling passages integrated into overmolded busbars, or other suitable cooling channel configurations. The inclusion of busbar cooling channels may allow better continuous performance since the whole battery system will be operating near the same temperature.

FIG. 4 shows a schematic diagram of an example busbar cooling channel formed in a cooling plate 400 configured to be integrated in an overmolded busbar. The cooling plate 400 may comprise a body 402 and a busbar cooling channel 404 formed on a top surface of the body. The body 402 may be constructed through additive manufacturing and may have a lattice structure design at least within the cooling channel. The cooling plate 400 may thermally contact a busbar, such as the first busbar 302 shown in FIG. 3, in order to dissipate heat from the busbar. The cooling plate 400 may be held in thermal contact with a busbar through the use a conformal coating. A conformal coating may be applied through the use of overmold technology or another suitable deposition method (e.g., brushing, spraying, dip coating). In this way, fluid coolant used in the cooling plate 400 may be kept from coming in contact with the electrically conductive busbar. However, other methods for incorporating the busbar cooling channel 404 into the busbar are possible, such as including a hollow passage within the busbar, etching the cooling channel on the top surface of the busbar (which may be maintained in an insulated state relative to coolant channel via a conformal coating on the busbar), or forming the cooling channel within the encapsulant/conformal coating itself.

The busbar cooling channel 404 may have an inlet 406 and an outlet 408. In some examples the inlet 406 may be on the opposite side of the cooling plate 400 than the outlet 408. In other examples, the inlet 406 and the outlet 408 may be on the same side or adjacent sides of the cooling plate 400. The busbar cooling channel 404 may start at the inlet 406 and end at the outlet 408. As such, the inlet 406 may be connected to the outlet 408 through the busbar cooling channel 404. In this way, a fluid coolant (e.g., liquid or gas) may flow through the busbar cooling channel 404 and may increase the heat dissipation capability of the cooling plate 400. In some examples, the busbar cooling channel 404 may run through the body 402 of the cooling plate 400 in a snaking pattern. In other examples, the busbar cooling channel 404 may take on any other suitable pattern, such as a straight line, a series of right angles, or a crisscross pattern. In still other examples, the busbar cooling channel 404 may be split into a plurality of cooling channels, each of which may start at the inlet 406 and end at the outlet 408.

FIG. 5 shows a schematic diagram of a plurality of cooling plates 500 each configured to be integrated with a respective busbar. The plurality of cooling plates 500 may include a first cooling plate 502, a second cooling plate 504, a third cooling plate 506, a fourth cooling plate 508, and fifth cooling plate 510. Each cooling plate may be in thermal contact with a busbar as described for the cooling plate 400 in FIG. 4. As illustrated, the plurality of cooling plates 500 may be positioned to be in thermal contact with a plurality of busbars, such as the plurality of busbars 300 in FIG. 3. For example, first cooling plate 502 may be in thermal contact with first busbar 302, second cooling plate 504 may be in thermal contact with second busbar 304, third cooling plate 506 may be in thermal contact with third busbar 306, fourth cooling plate 508 may be in thermal contact with fourth busbar 308, and fifth cooling plate 510 may be in thermal contact with fifth busbar 310.

Each cooling plate in the plurality of cooling plates 500 may have the same width and length as the corresponding busbar from the plurality of busbars 300 (e.g., first cooling plate 502 has the same width and length as the first busbar 302, etc.). As such, the plurality of cooling plates 500 may be positioned directly over the plurality of busbars 300 so that the plurality of busbars 300 are hidden from view when viewed from a top-down view. In some examples, the plurality of cooling plates 500 may include a different number of cooling plates, such as more or less than five cooling plates. Each cooling plate in the plurality of cooling plates 500 may have a cooling channel, an inlet, and an outlet, similar to the cooling plate 400 in FIG. 4.

FIG. 6 shows an example cooling system 600 configured to cool an electric energy storage device, such as electric energy storage device 132 and/or electric energy storage device 200. The cooling system 600 may include a heat exchanger 616, a first tube 612, and a second tube 614. The cooling system 600 may also include a plurality of cooling plates 602. In some examples, the plurality of cooling plates 602 may include a first cooling plate 604, a second cooling plate 606, a third cooling plate 608, and a fourth cooling plate 610, as illustrated in FIG. 6. In other examples, the plurality of cooling plates 602 may include more or less than four cooling plates. In some examples, the cooling system 600 may only include a pump (not shown in FIG. 6), such as pump 161 of FIG. 1, the heat exchanger 616, the first tube 612, the second tube 614, and the plurality of cooling plates 602, such that no other components other than the plurality of cooling plates 602 are cooled via coolant flowing in the cooling system 600. In other examples, the cooling system 600 may include additional components.

Each of the cooling plates in the plurality of cooling plates 602 may be similar to the cooling plate 400 from FIG. 4. In this way, the first cooling plate 604, the second cooling plate 606, the third cooling plate 608, and the fourth cooling plate 610 may each have a body constructed through additive manufacturing, a busbar cooling channel to carry a fluid (e.g., liquid or gas) coolant, and an inlet and an outlet through which the fluid coolant may enter and exit the cooling channel, respectively. Each cooling plate in the plurality of cooling plates 602 may be in thermal contact with a busbar as described for the cooling plate 400 in FIG. 4, such that the plurality of cooling plates 602 may be positioned to be in thermal contact with a plurality of busbars of an electric energy storage device. Each cooling plate in the plurality of cooling plates 602 may have the same width and length as the corresponding busbar from the plurality of busbars (e.g., the first cooling plate 604 has the same width and length as the first busbar, etc.). As such, the plurality of cooling plates 602 may be positioned directly over/on top of the plurality of busbars. Each busbar in the plurality of busbars may be in electrical contact with the conducting terminals of an electric energy storage device, such as the electric energy storage device 200 from FIG. 2. In some examples, the plurality of cooling plates 602 may include four cooling plates organized as shown in FIG. 6. In other examples, the plurality of cooling plates 602 may include five cooling plates organized similarly to the plurality of cooling plates 500 in FIG. 5.

The cooling system 600 may include a fluid coolant, such as water. The fluid coolant may be cooled by the heat exchanger 616, which may be a finned tube heat exchanger, a shell and tube heat exchanger, a plate heat exchanger, or other suitable kind of heat exchanger. The fluid coolant may be pumped from the heat exchanger 616 directly into the first tube 612, which may be directly connected to the heat exchanger 616. In some examples, the fluid coolant may flow from the heat exchanger 616 into one or more additional components of the cooling system 600 before flowing into the first tube 612. The first tube 612 may have a first branch point 618, at which the first tube 612 may split into a plurality of secondary tubes such as the first secondary tube 620. In some examples, the first tube 612 may not have the first branch point 618. In other examples, there may be one or more branch points in addition to the first branch point 618 on the first tube 612. The fluid coolant may flow from the first tube 612, through the first branch point 618, and directly into the plurality of secondary tubing, including the first secondary tube 620.

Each tube in the plurality of secondary tubing, such as the first secondary tube 620, may be directly connected to the inlet of one of the plurality of cooling plates 602, such as the first inlet 622 of the first cooling plate 604. The fluid coolant may therefore flow from the plurality of secondary tubing directly into the inlets of the plurality of cooling plates 602. The fluid coolant may then flow from the inlet of each cooling plate in the plurality of cooling plates 602, such as the first inlet 622, through the cooling channel of the same cooling plate, such as the first cooling channel 624. The cooling channel of each cooling plate in the plurality of cooling plates 602, such as the first cooling channel 624, may be directly connected to the outlet of the same cooling plate, such as the first outlet 626. In this way, fluid coolant may flow from the cooling channel of each cooling plate in the plurality of cooling plates 602 directly to the outlet of the same cooling plate.

The second tube 614 may have a second branch point 630, at which the second tube 614 may split into a second plurality of secondary tubes such as the second secondary tube 628. In some examples, the second tube 614 may not have the second branch point 630. In other examples, there may be one or more branch points in addition to the second branch point 630 on the second tube 614. The fluid coolant may flow from the outlet of each cooling plate, such as the first outlet 626, directly into the second plurality of secondary tubing, such as the second secondary tube 628. The parallel flows of fluid coolant may then rejoin at the second branch point 630 where the fluid coolant may flow directly into the second tube 614. From the second tube 614, the fluid coolant may then flow directly into the heat exchanger 616, which may be directly connected to the second tube 614. In some examples, the fluid coolant may flow from second tube 614 into one or more additional components of the cooling system 600 before flowing into the heat exchanger 616.

As shown in FIG. 6, the plurality of cooling plates 602 may be arranged in parallel within the cooling system 600. In this way, each cooling plate/busbar cooling channel may receive coolant from the heat exchanger directly and without flowing through another busbar cooling channel before, e.g., the coolant may not flow out of one cooling plate and into another cooling plate without first flowing through the heat exchanger 616.

In other examples, the plurality of cooling plates 602 may be arranged in series within the cooling system 600. In this way, coolant may flow from the heat exchanger 616 directly to a first busbar cooling channel; from the first busbar cooling channel to a second busbar cooling channel; from the second busbar cooling channel to a third busbar cooling channel; and so forth until the coolant has traversed each busbar cooling channel and the coolant then flows back to the heat exchanger. In some examples, the cooling plate/busbar cooling channel corresponding to the busbar that is expected to reach the highest temperature (e.g., the fourth busbar 308 of the plurality of busbars 300) may receive coolant directly from the heat exchanger, to thereby preferentially cool the busbar that is expected to reach the highest temperature. The coolant may then flow through each of the reaming busbar cooling channels before returning to the heat exchanger 616. The busbar cooling channel corresponding to the busbar that is expected to reach the lowest temperature (e.g., the fifth busbar 310 of the plurality of busbars 300) may be the last busbar cooling channel that the coolant flows through before returning to the heat exchanger 616. In still further examples, the coolant may flow through the busbar cooling channels in a parallel-series arrangement where the coolant splits into two parallel flow paths, with one flow path extending through two or more busbar cooling channels in series and the other flow path extending through the remaining busbar cooling channels in series.

Thus, cooling system 600 may include a heat exchanger, a pump, a plurality of busbar cooling channels (e.g., each formed in a respective cooling plate), and corresponding conduit/tubes to facilitate the flow of coolant from the heat exchanger, to each busbar cooling channel, and back to the heat exchanger. The coolant may flow through each busbar cooling channel in parallel, such that each busbar cooling channel receives coolant from the heat exchanger and without the coolant first passing through another busbar cooling channel. In doing so, each busbar cooling channel may be supplied coolant at substantially the same temperature.

FIG. 7 shows a second cooling system 700. The second cooling system 700 may be substantially similar to the cooling system 600 shown in FIG. 6 and may include the plurality of cooling plates 602, such as the first cooling plate 604, the second cooling plate 606, the third cooling plate 608, and the fourth cooling plate 610. The plurality of cooling plates 602 may be in thermal contact with a plurality of busbars, as described in FIG. 6. The second cooling system 700 may also include the heat exchanger 616, the first tube 612, and the second tube 614. The fluid coolant in the second cooling system 700 may follow the same path as the fluid coolant in the cooling system 600 except that the flow of coolant in the second cooling system 700 may be controlled via a plurality of coolant control elements 702 including a first coolant control element 704, a second coolant control element 706, a third coolant control element 708, and a fourth coolant control element 710. Each control element of the plurality of coolant control elements 702 may be positioned to control flow of coolant through a respective busbar cooling channel.

In some examples, each coolant control element of the plurality of coolant control elements 702 may be located upstream of a respective busbar cooling channel inlet, such as within a coolant tube of the plurality of secondary tubing, such as the first secondary tube 620, as illustrated in FIG. 7. In other examples, the plurality of coolant control elements 702 may be located in the inlets of the plurality of cooling plates 602, such as the first inlet 622, the outlets of the plurality of cooling plates 602, such as the first outlet 626, or downstream of the outlet in a coolant tube of the second plurality of secondary tubing, such as the second secondary tube 628. In still other examples, the plurality of coolant control elements 702 may be located within the cooling channels of the plurality of cooling plates, such as the first cooling channel 624.

In some examples, each coolant control element in the plurality of coolant control elements 702 may be controlled (whether actively or passively) in response to the temperature of at least one part of the second cooling system 700. In this way, each coolant control element in the plurality of coolant control elements 702 may increase or decrease the flow of coolant depending on the localized temperature at that coolant control element or corresponding cooling plate (e.g., the first coolant control element 704 and the first cooling plate 604, etc.). In this way, the second cooling system 700 may have higher coolant flow rates to the cooling plates in the plurality of cooling plates 602 that have higher temperatures and lower coolant flow rates to the cooling plates that have lower temperatures. The plurality of coolant control elements 702 may therefore help to balance the temperature across the plurality of cooling plates 602 as well as an electric energy storage device that may be in thermal contact with the busbars corresponding to each of the plurality of cooling plates 602.

In some examples, the plurality of coolant control elements 702 may be thermally-reactive valves, e.g., of a thermostat style (e.g., flat diaphragm or squeeze-push), containing wax or another suitable thermostatic element. As the localized temperature of a coolant control element increases, the thermostatic element may expand and change the shape or position of at least a portion of the coolant control element. In other examples, the plurality of coolant control elements 702 may be actively-controlled valves that may be opened or closed based on a command sent by a controller. The actively-controlled valves may include electric (e.g., solenoid) actuators (e.g., plunger-type actuator or pivoted-armature actuator), hydraulic actuators, or another suitable type of actuator. Either the localized temperature or a remote temperature may be measured and used to determine the coolant flow rate through each coolant control element in the plurality of coolant control elements 702, as will be explained in more detail below with respect to FIG. 10.

In still other examples, the plurality of coolant control elements 702 may include shape memory alloy (SMA) actuated valves, such as the SMA actuated valve 1100 shown in FIG. 11. Each SMA actuated valve may include a SMA actuator that may be constructed of a nickel titanium alloy or other suitable material. Each coolant control element may have an SMA actuator with an original shape that can be deformed when cold and will return to its original shape when heated. The SMA actuator may take the form of a rod or torsion spring, and be coupled to a flap via a hinge-type mechanism. Each SMA actuated valve flap may be in a partially closed state when the localized temperature is on the lower end of the operating range. The flow of the coolant may push on the flap and hold it in the partially closed state. As the localized temperature increases, the heat may actuate the SMA and force the flap against the flow of coolant and into a more open state. The flow rate of coolant through the SMA actuated valve may be increased as the flap becomes more open. As the localized temperate cools, the SMA may relax and allow the flow of coolant to return the flap to the original partially closed state. Each SMA actuator may be positioned in a suitable location that may be proximate the flap or distal from the flap. For example, each SMA actuator may be positioned to react to the temperature of coolant at the corresponding flap. In other examples, each SMA actuator may be positioned on a corresponding busbar, between the corresponding busbar and the underlying battery cells, between two battery cells, or another suitable location.

FIG. 8 shows a third cooling system 800. The third cooling system 800 may be substantially similar to the cooling system 600 shown in FIG. 6 and may include the plurality of cooling plates 602, such as the first cooling plate 604, the second cooling plate 606, the third cooling plate 608, and the fourth cooling plate 610. The plurality of cooling plates 602 may be in thermal contact with a plurality of busbars, as described in FIG. 6. The third cooling system 800 may also include the heat exchanger 616, the first tube 612, and the second tube 614. The coolant in the third cooling system 800 may follow the same path through the busbar cooling channels as the coolant in the cooling system 600. The third cooling system 800 may also include a plurality of additional cooling channels 801 configured to provide additional cooling to the busbars.

The plurality of additional cooling channels 801 may include a first additional cooling channel 804, a second additional cooling channel 806, a third additional cooling channel 808, and a fourth additional cooling channel 810 in or on the first cooling plate 604, the second cooling plate 606, the third cooling plate 608, and the fourth cooling plate 610, respectively. The plurality of additional cooling channels 801 may be in thermal contact with the busbars such that each cooling channel in the plurality of additional cooling channels may transfer heat away from a respective busbar. In some examples, the plurality of additional cooling channels 801 may be integrated in the overmolded busbar similarly to the plurality of cooling plates 602. In other examples, the plurality of additional cooling channels 801 may be outside of the overmolded busbars (e.g., in face sharing contact with the conformal coating of the overmolded busbars).

The third cooling system 800 may also include a plurality of coolant control elements 802, similar to the plurality of coolant control elements 702 described in FIG. 7. The plurality of coolant control elements 802 may include a first coolant control element 803, a second coolant control element 805, a third coolant control element 807, and a fourth coolant control element 809 positioned within the first additional cooling channel 804, the second additional cooling channel 806, the third additional cooling channel 808, and the fourth additional cooling channel 810, respectively.

Each cooling channel in the plurality of additional cooling channels 801 may be directly connected to the first tube 612 and the second tube 614 through at least one additional branch point, similar to the first branch point 618 and the second branch point 630. Fluid coolant may flow directly from the first tube 612 into the plurality of additional cooling channels 801 and through the plurality of coolant control elements 802. The fluid coolant may then flow from the plurality of additional cooling channels 801 directly into the second tube 614.

The plurality of additional cooling channels 801 may be arranged in parallel with respect to each other and to all other cooling channels within the plurality of cooling plates 602, such as the first cooling channel 624. In this way, the fluid coolant may not flow out of one additional cooling channel, such as the first additional cooling channel 804, and into any other cooling channel without first flowing through the heat exchanger 616.

FIG. 9 shows a fourth cooling system 900. The fourth cooling system 900 may be substantially similar to the third cooling system 800 shown in FIG. 8 and may include the plurality of cooling plates 602, such as the first cooling plate 604, the second cooling plate 606, the third cooling plate 608, and the fourth cooling plate 610. The plurality of cooling plates 602 may be in thermal contact with a plurality of busbars, as described in FIG. 6. The fourth cooling system 900 may also include the heat exchanger 616, the first tube 612, and the second tube 614. However, rather than including an additional cooling channel for each busbar as in the third cooling system 800, the fourth cooling system 900 may only include subset of additional cooling channels 901 and a subset of coolant control elements 902 such that only a portion of the busbars are cooled via the additional cooling channels. The coolant in the fourth cooling system 900 may flow through the subset of additional cooling channels 901 and the subset of coolant control elements 902 in the same way that the coolant of the third cooling system 800 flowed through the plurality of additional cooling channels 801 and the plurality of coolant control elements 802.

The subset of additional cooling channels 901 may be used to target additional coolant flow to the cooling plates in the plurality of cooling plates 602 that are in thermal contact with busbars that are expected to reach higher temperatures. The targets of additional coolant flow may be determined through simulations of high load/energy demand excursion, such as after a vehicle within which the plurality of cooling plates 602 is positioned is simulated to be propelled at prolonged high speed. In some examples, the subset of additional cooling channels may include the second additional cooling channel 806 and the third additional cooling channel 808 within the second cooling plate 606 and the third cooling plate 608, respectively, as illustrated in FIG. 9. In these examples, the first cooling plate 604 and the fourth cooling plate 610 may not have additional cooling channels, and therefore may have coolant passing through the inlet, such as the first inlet 622, the cooling channel, such as the first cooling channel 624, and the outlet, such as the first outlet 626, as described for the cooling system 600 in FIG. 6. As such, the second cooling plate 606 and the third cooling plate 608 of the plurality of cooling plates 602 may be capable of dissipating larger amounts of heat than the first cooling plate 604 and the fourth cooling plate 610 of the plurality of cooling plates 602.

In some examples, the subset of additional cooling channels 901 may include more or less than two additional cooling channels. In other examples, the subset of additional cooling channels 901 may be positioned in the first cooling plate 604 and the second cooling plate 606, or in any other combination of two cooling plates from the plurality of cooling plates 602. In some examples, the subset of additional cooling channels 901 may be shaped, sized, or positioned in such a way that coolant flows over specific areas of the plurality of cooling plates 602 that are in thermal contact with busbars that are expected to reach the highest temperatures. In some examples, the subset of additional cooling channels may be configured such that coolant spends more time over a hot spot, such as the hot spot 326 in FIG. 3, and less or no time over cold spots, such as the cold spot 324 in FIG. 3. In some example, the same approach may be taken for the original cooling channels within the plurality of cooling plates 602 as well, such that the busbar cooling channels are not necessarily uniformly shaped or positioned, or positioned to uniformly cool the underlying busbar.

As explained previously, the fourth cooling system 900 may be configured to include five busbar cooling channels sized and positioned as shown in FIG. 5 and positioned on the busbars shown in FIG. 3 (which are turn positioned on the electric energy storage device of FIG. 2) to form a plurality of overmolded busbars. In such examples, the plurality of overmolded busbars includes a first overmolded busbar positioned at a longitudinal center of the electric energy storage device on a first side of the electric energy storage device (e.g., where the first side includes the positive tabs), a second overmolded busbar positioned at first longitudinal end of the electric energy storage device on the first side of the electric energy storage device, and a third overmolded busbar positioned at second longitudinal end of the electric energy storage device on the first side of the electric energy storage device. The fourth cooling system, in such examples, may further include one or more additional cooling channels that includes a first cooling channel positioned on top of the first overmolded busbar, but the second and third overmolded busbars may not include an additional cooling channel positioned thereon.

FIG. 10 shows a flowchart illustrating a method 1000 for controlling coolant flow in a cooling system configured to cool an electric energy storage device, such as any of the cooling systems of FIGS. 6-9. Instructions for carrying out method 1000 and the rest of the methods included herein may be executed by a controller, such as controller 12 of FIG. 1, based on instructions stored on a memory of the controller and in conjunction with signals received from sensors of the vehicle system, such as the sensors described above with reference to FIG. 1. The controller may employ engine actuators of the vehicle system to adjust cooling system operation, according to the methods described below.

At 1002, method 1000 may determine or infer the temperature across an electric energy storage device, such as the electric energy storage device 200 shown in FIG. 2. As shown in FIG. 2, there may be varying temperature across the electric energy storage device 200. The temperature may be measured at any suitable number of locations across the electric energy storage device via one or more temperature sensors (e.g., temperature sensors 110 of FIG. 1). In some examples, the temperature may be measured at the surface of the batteries within the electric energy storage device, at the busbars that are electrically connected to the electric energy storage device, and/or in the cooling plates/cooling channels that are in thermal contact with the busbars. In other examples, the temperature across the electric energy storage device may be inferred through the use of modeling or another suitable method. The inferred temperature may be based on one or more suitable vehicle operating conditions (e.g., vehicle speed, wheel torque, etc.).

At 1004, method 1000 may determine if any of the measured or inferred temperatures are greater than a threshold temperature. The threshold temperature may be an upper value of a range of temperatures for efficient battery performance, such as a value in a range of 40-45° C. If all of the temperatures are below the threshold temperature, coolant in the cooling system may remain stagnant and may not flow through the busbar cooling channels (e.g., the busbar cooling channels formed in the plurality of cooling plates of the cooling systems of any of FIGS. 5-9). In some examples, a coolant pump configured to pump coolant through the cooling system may not be activated until at least one of the measured or inferred temperatures rises above the threshold temperature. In other examples, the pump may be active whenever the vehicle is on and coolant may bypass the busbar cooling channels or the heat exchanger until at least one of the measured or inferred temperatures rises above the threshold temperature. The method 1000 may return to 1002, where the temperature across the electric energy storage device may be measured or inferred again. If the at least one temperature is above the threshold temperature at 1004, the method 1000 may proceed to 1006.

At 1006, the coolant pump is activated to flow coolant through the busbar cooling channels. The coolant may enter each busbar cooling channel in parallel from the heat exchanger, flow through an inlet, flow through the busbar cooling channel, and exit each busbar cooling channel through an outlet, in parallel and back to the heat exchanger. In other examples, the coolant may flow through two or more busbar cooling channels in series, e.g., the coolant may enter a first busbar cooling channel and then exit the first busbar cooling channel and flow to a second busbar cooling channel, then a third busbar cooling channel, etc. As such, the coolant flowing through the cooling channels of the cooling plates may dissipate additional heat from the busbars that are in thermal contact with the cooling plates. Additionally or alternatively, particularly in examples where the coolant pump is activated before the threshold temperature is reached, the cooling system may be adjusted to cool the coolant by flowing the coolant through the heat exchanger in response to the threshold temperature being reached.

At 1008, the method 1000 may include adjusting the position of one or more coolant control elements based on the measured or inferred temperature across the electric energy storage device. In some examples, adjusting the position of coolant control elements based on temperature may include opening only the coolant control elements positioned at areas above the threshold temperature, as indicated at 1010. As explained above with respect to FIG. 7, the coolant control elements may include actively-controlled valves, such as solenoid valves, that can be independently controlled (e.g., opened or closed) based on the temperature of a corresponding busbar and/or underlying battery cells to target coolant flow to identified hot spots of the electric energy storage device and without unnecessarily cooling other, colder regions of the electric energy storage device (which can lower battery performance). For example, the temperature at a first busbar and a third busbar, such as the first busbar and the third busbar described in FIG. 7, may be above the threshold temperature while the temperature at a second busbar and a fourth busbar, such as the second busbar and fourth busbar described in FIG. 7, may be below the threshold temperature. As such, a first coolant control element and a third coolant control element, such as the first coolant control element 704 and the third coolant control element 708 in FIG. 7, may be open while a second coolant control element and a fourth coolant control element, such as the second coolant control element 706 and the fourth coolant control element 710 in FIG. 7, may be closed. In this way, coolant may flow through a first busbar cooling channel and a third busbar cooling channel, such as the busbar cooling channels of the first cooling plate 604 and the third cooling plate 608 in FIG. 7, to dissipate additional heat from the first busbar and the third busbar.

In some examples, adjusting the position of the one or more coolant control elements based on temperature may include adjusting the orifice size of the one or more coolant control elements based on the temperature of each busbar, as indicated at 1012. In examples where the coolant control elements are continuously adjustable valves configured to be controlled to more than two orifice sizes (e.g., where the valves can be opened by specific amounts beyond just opened and closed), the orifice size/amount each coolant control element is open may be adjusted based on the corresponding busbar temperature or underlying battery cell temperature. For example, the temperature at a first busbar and a third busbar, such as the first busbar and the third busbar described in FIG. 7, may be above the threshold temperature. As such, a first coolant control element and a third coolant control element, such as the first coolant control element 704 and the third coolant control element 708 in FIG. 7, may be open. In some examples, the temperature at the first busbar may be higher than the temperature at the third busbar. As such, the first coolant control element may be open by a larger amount than the third coolant control element. In this way, different amounts of coolant may flow through each busbar cooling channel. More coolant may flow through a first busbar cooling channel, such as the busbar channel of the first cooling plate 604 in FIG. 7, relative to the coolant that may flow through a third busbar cooling channel, such as the busbar cooling channel of the third cooling plate 608 in FIG. 7. The coolant flow through the first busbar cooling channel and the third busbar cooling channel may dissipate additional heat from the first busbar and the third busbar, respectively, as the first cooling plate and hence first busbar cooling channel is in thermal contact with the first busbar and the third cooling plate and hence third busbar cooling channel is in thermal contact with the third busbar. Additionally, the first busbar may dissipate a larger amount of heat due to the increased coolant flow through the first busbar cooling channel.

In some examples, adjusting the position of the one or more coolant control elements based on temperature may include adjusting the coolant control elements of additional cooling channels based on the measured or inferred temperatures, as indicated at 1014. As explained above with respect to FIGS. 8 and 9, the cooling system may include additional cooling channels positioned adjacent some or all of the busbars/busbar cooling channels. Coolant flow through the additional cooling channels may be controlled similarly as explained above for the busbar cooling channels so that the additional cooling channels may be employed to dissipate heat only when demanded. For example, the temperature at a first busbar, such as the first busbar described in FIG. 8, may be above the threshold temperature. As such, coolant may be pumped through a first cooling channel, such as the first cooling channel 624 in FIG. 8, within a first cooling plate, such as the first cooling plate 604, which is in thermal contact with the first busbar. In some examples, the coolant flow through the first busbar cooling channel may not be sufficient to cool the corresponding busbar or underlying battery cells and thus it may be advantageous to flow additional coolant through the additional cooling channel, such as the first additional cooling channel 804 in FIG. 8. As such, a first coolant control element, such as the first coolant control element 803 in FIG. 8, may be open. In this way, coolant may flow through both the first busbar cooling channel and the additional cooling passage associated with the first busbar and may dissipate additional heat from the first busbar.

In this way, by adjusting the amount of coolant flowing through each coolant control element, the cooling system is granted a higher degree of temperature control relative to systems where a coolant flow rate through each cooling channel is the same. As such, different regions of the cooling system, for example specific cooling plates containing cooling channels, may receive more coolant and therefore may be able to dissipate larger amounts of heat from busbars that are in thermal contact. The ability to vary the rate of coolant flow throughout the cooling system may allow an electric energy storage device that is being cooled by the cooling system to maintain more optimal temperatures across the device.

FIG. 11 shows an SMA actuated valve 1100, such as the first coolant control element 704 of FIG. 7, a busbar cooling channel 1124, such as the busbar cooling channel 404 of FIG. 4, a busbar 1102, such as the first busbar 302 of FIG. 3, and an electric energy storage device 1126, such as the electric energy storage device 200 of FIG. 2. FIG. 11 also includes Cartesian coordinate system 1199 to orient the views.

The electric energy storage device 1126 may be comprised of a plurality of batteries 1108 (also referred to as battery cells), including at least a first battery 1110 and a second battery 1112. The first battery 1110 may be adjacent to the second battery 1112 along the x-axis. In the example illustrated in FIG. 11, the plurality of batteries 1108 includes four batteries, but it is to be appreciated that more or fewer batteries may be included without departing from the scope of this disclosure. Each battery cell of the plurality of batteries 1108 may have a set of electric tabs, such as a positive tab 1122 of the first battery 1110, which extend outside of the battery core along the y-axis. The electric energy storage device 1126 may include an outer core that houses the plurality of batteries 1108, which is removed from FIG. 11 for visual clarity.

The busbar 1102 may be positioned to be in electrical contact with the electric tabs, including the positive tab 1122, of a plurality of batteries 1108. The busbar 1102 may also be in thermal contact with the electric energy storage device 1126, similar to the thermal contact between the plurality of busbars 300 of FIG. 3 and the electric energy storage device 200 of FIG. 2. The busbar 1102 may also be in thermal contact with the busbar cooling channel 1124. As such, the busbar cooling channel 1124 may dissipate heat from the busbar 1102, similar to the first cooling channel 624 and the respective busbar of FIG. 6.

The busbar cooling channel 1124 may include a top 1128 and a bottom 1130. In some examples, the bottom 1130 may be in face sharing contact with the busbar 1102. The busbar cooling channel 1124 may also include a first wall 1104 and a second wall 1106. One or more of the top 1128, the bottom 1130, the first wall 1104, and the second wall 1106 may be constructed through additive manufacturing and may be overmolded onto the busbar, as described for FIG. 4. Coolant may flow through the busbar cooling channel 1124 and help to dissipate heat from the busbar 1102.

The SMA actuated valve 1100 may include an SMA actuator 1114, a hinge 1116, a valve flap 1118, and a valve stop 1120. The SMA actuated valve 1100 may be positioned in order to control the flow of coolant through the busbar cooling channel 1124. As such, the hinge 1116, the valve flap 1118, the valve stop 1120, and at least a portion of the SMA actuator 1114 may each be positioned within the busbar cooling channel 1124. In some examples, the hinge 1116, the valve flap 1118, the valve stop 1120, and at least a portion of the SMA actuator 1114 may each be positioned within intermediate tubing, such as the first secondary tube 620 of FIG. 6, and not within the busbar cooling channel 1124.

Similar to the SMA actuator described in FIG. 7, the SMA actuator 1114 may be constructed of a nickel titanium alloy. As such, the SMA actuator 1114 may have an original shape that can be deformed when cold and will return to its original shape when heated. In some examples, the SMA actuator 1114 may take the form of a rod or torsion spring. The valve flap 1118 may be coupled to the SMA actuator 1114 through the hinge 1116. As such, structural changes in the SMA actuator 1114 due to heating or cooling may rotate the hinge 1116, and therefore affect the position of the valve flap 1118. In some examples, when the localized temperature of the SMA actuator 1114 is on the lower end of the operating range, the valve flap 1118 may be in a partially closed state. The flow of the coolant may push on the valve flap 1118, holding it against the valve stop 1120. As the localized temperature of the SMA actuator 1114 increases, the heat may actuate the SMA actuator 1114 and force the valve flap 1118 away from the valve stop 1120 and against the flow of coolant (e.g., into a more open state). The flow rate of coolant through the SMA actuated valve 1100 may increase as the valve flap 1118 moves into a more open state. As the localized temperate cools, the SMA actuator 1114 may relax and allow the flow of coolant to return the valve flap 1118 back to the valve stop 1120 (e.g., to the partially closed state).

The SMA actuator 1114 may extend from the hinge 1116 into the electric energy storage device 1126. As such, at least a portion of the SMA actuator 1114 may be positioned within plurality of batteries 1108. In some examples, at least a portion of the SMA actuator 1114 may be positioned in between the first battery 1110 and the second battery 1112, as shown in FIG. 11. In this way, the temperature of the first battery 1110 and/or the temperature of the second battery 1112 may determine the localized temperature of the SMA actuator 1114. As the localized temperature of the first battery 1110 and/or the second battery 1112 increases, coolant flow in the busbar cooling channel 1124 above the first battery 1110 and/or the second battery 1112 may be increased. Similarly, as the localized temperature of the first battery 1110 and/or the second battery 1112 decreases, coolant flow in the busbar cooling channel 1124 above the first battery 1110 and/or the second battery 1112 may be decreased.

In other examples, the SMA actuator 1114 may be positioned in between any other combination of batteries of the plurality of batteries 1108. In still other examples, the SMA actuator 1114 may only extend from the hinge 1116 into the busbar 1102, and not into the electric energy storage device 1126.

A technical effect of differentially cooling a plurality of busbars based on a plurality of temperatures by flowing different amounts of coolant through one or more respective busbar cooling channels and/or by flowing coolant through one or more respective additional cooling channels is that an electric energy storage device may be maintained at a more uniform and consistent temperature, which may prolong the life of the electric energy storage device.

The disclosure also provides support for a system, comprising: an electric energy storage device comprising a plurality of battery cells, and a plurality of busbars coupled to the electric energy storage device, each busbar including a respective busbar cooling channel fluidly coupled to a cooling system including a heat exchanger, wherein coolant in the cooling system is configured to flow through each respective busbar cooling channel. In a first example of the system, the system further comprises: a plurality of coolant control elements, wherein each coolant control element is configured to control flow of coolant through a respective busbar cooling channel. In a second example of the system, optionally including the first example, the plurality of coolant control elements comprises a plurality of actively-controlled valves. In a third example of the system, optionally including one or both of the first and second examples, the plurality of coolant control elements comprises a plurality of thermally-reactive variable orifices. In a fourth example of the system, optionally including one or more or each of the first through third examples, the plurality of coolant control elements comprises a plurality of shape memory alloy (SMA) actuated valves. In a fifth example of the system, optionally including one or more or each of the first through fourth examples, each SMA actuated valve comprises a SMA actuator coupled to a valve flap via a hinge, wherein the valve flap is configured to move in response to a thermally-mediated shape change of the SMA actuator. In a sixth example of the system, optionally including one or more or each of the first through fifth examples, the SMA actuator is positioned within the electric energy storage device and the valve flap is positioned within a respective busbar cooling channel or in a coolant tube coupled to the respective busbar cooling channel. In a seventh example of the system, optionally including one or more or each of the first through sixth examples, coolant in the cooling system is configured to flow through each respective busbar cooling channel in parallel. In an eighth example of the system, optionally including one or more or each of the first through seventh examples, each respective busbar cooling channel is comprised of a plate overmolded on the respective busbar, the plate formed with a depression that, when overmolded, forms the respective busbar cooling channel. In a ninth example of the system, optionally including one or more or each of the first through eighth examples, the system further comprises: one or more additional cooling channels positioned on top of one or more respective overmolded busbars. In a tenth example of the system, optionally including one or more or each of the first through ninth examples, each battery cell includes a positive tab and a negative tab, such that the electric energy storage device includes a plurality of positive tabs arranged on a first side of the electric energy storage device and a plurality of negative tabs arranged on a second side of the electric energy storage device, wherein the plurality of overmolded busbars includes a first overmolded busbar positioned at a longitudinal center of the electric energy storage device on the first side of the electric energy storage device, a second overmolded busbar positioned at first longitudinal end of the electric energy storage device on the first side of the electric energy storage device, and a third overmolded busbar positioned at second longitudinal end of the electric energy storage device on the first side of the electric energy storage device, and wherein the one or more additional cooling channels includes a first cooling channel positioned on top of the first overmolded busbar, wherein the second and third overmolded busbars do not include an additional cooling channel positioned thereon.

The disclosure also provides support for a system, comprising: an electric energy storage device comprising a plurality of battery cells, a plurality of busbars coupled to the electric energy storage device, each busbar including a respective busbar cooling channel fluidly coupled to a cooling system including a heat exchanger, wherein coolant in the cooling system is configured to flow through each respective busbar cooling channel, one or more actively-controlled valves configured to control flow of the coolant in the cooling system, and a controller configured to adjust a position of the one or more actively-controlled valves based on a plurality of temperatures across the electric energy storage device. In a first example of the system, the system further comprises: a plurality of thermistors positioned across the electric energy storage device, and wherein the controller is configured to measure the plurality of temperatures based on output from the plurality of thermistors. In a second example of the system, optionally including the first example, the one or more actively-controlled valves includes a plurality of actively-controlled valves, each actively-controlled valve positioned to control the flow of the coolant through a respective busbar cooling channel. In a third example of the system, optionally including one or both of the first and second examples, the plurality of temperatures includes a respective temperature of each busbar of the plurality of busbars and wherein the controller is configured to adjust a position of each actively-controlled valve independently based on a corresponding respective temperature. In a fourth example of the system, optionally including one or more or each of the first through third examples, each busbar cooling channel is housed in an over-molding of a respective busbar and further comprising an additional cooling channel positioned on top of one of the over-moldings, and wherein the one or more actively-controlled valves includes an actively-controlled valve configured to control the flow of the coolant through the additional cooling channel.

The disclosure also provides support for a method, comprising: measuring or inferring a plurality of temperatures across an electric energy storage device comprising a plurality of battery cells and a plurality of busbars coupled to the electric energy storage device, each busbar including a respective over-molding housing a respective busbar cooling channel fluidly coupled to a cooling system including a heat exchanger, and wherein one or more of the plurality of busbars further includes a respective additional cooling channel positioned adjacent a respective over-molding, and differentially cooling the plurality of busbars based on the plurality of temperatures by flowing different amounts of coolant through one or more respective busbar cooling channels and/or by flowing coolant through one or more respective additional cooling channels. In a first example of the method, flowing different amounts of coolant through one or more respective busbar cooling channels comprises flowing coolant through some but not all of the one or more respective busbar cooling channels. In a second example of the method, optionally including the first example, flowing different amounts of coolant through one or more respective busbar cooling channels comprises controlling one or more actively-controlled valves of a plurality of actively-controlled valves, each actively-controlled valve of the plurality of actively-controlled valves positioned to control flow of coolant through a respective busbar cooling channel. In a third example of the method, optionally including one or both of the first and second examples, differentially cooling the plurality of busbars based on the plurality of temperatures by flowing different amounts of coolant through one or more respective busbar cooling channels and/or by flowing coolant through one or more respective additional cooling channels comprises flowing coolant through each respective busbar cooling channel and flowing coolant through each respective additional cooling channel, where some but not all busbars of the plurality of busbars is positioned adjacent an additional cooling channel.

Note that the example control and estimation routines included herein can be used with various engine and/or vehicle system configurations. The control methods and routines disclosed herein may be stored as executable instructions in non-transitory memory and may be carried out by the control system including the controller in combination with the various sensors, actuators, and other engine hardware. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the example embodiments described herein, but is provided for ease of illustration and description. One or more of the illustrated actions, operations, and/or functions may be repeatedly performed depending on the particular strategy being used. Further, the described actions, operations, and/or functions may graphically represent code to be programmed into non-transitory memory of the computer readable storage medium in the engine control system, where the described actions are carried out by executing the instructions in a system including the various engine hardware components in combination with the electronic controller.

It will be appreciated that the configurations and routines disclosed herein are exemplary in nature, and that these specific embodiments are not to be considered in a limiting sense, because numerous variations are possible. For example, the above technology can be applied to V-6, I-4, I-6, V-12, opposed four, and other engine types. Moreover, unless explicitly stated to the contrary, the terms “first,” “second,” “third,” and the like are not intended to denote any order, position, quantity, or importance, but rather are used merely as labels to distinguish one element from another. The subject matter of the present disclosure includes all novel and non-obvious combinations and sub-combinations of the various systems and configurations, and other features, functions, and/or properties disclosed herein.

As used herein, the term “approximately” is construed to mean plus or minus five percent of the range unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A system, comprising:
an electric energy storage device comprising a plurality of battery cells; and
a plurality of busbars coupled to the electric energy storage device, each busbar including a respective busbar cooling channel fluidly coupled to a cooling system including a heat exchanger, wherein coolant in the cooling system is configured to flow through each respective busbar cooling channel.

2. The system of claim 1, further comprising a plurality of coolant control elements, wherein each coolant control element is configured to control flow of coolant through a respective busbar cooling channel.

3. The system of claim 2, wherein the plurality of coolant control elements comprises a plurality of actively-controlled valves.

4. The system of claim 2, wherein the plurality of coolant control elements comprises a plurality of thermally-reactive variable orifices.

5. The system of claim 2, wherein the plurality of coolant control elements comprises a plurality of shape memory alloy (SMA) actuated valves.

6. The system of claim 5, wherein each SMA actuated valve comprises a SMA actuator coupled to a valve flap via a hinge, wherein the valve flap is configured to move in response to a thermally-mediated shape change of the SMA actuator.

7. The system of claim 6, wherein the SMA actuator is positioned within the electric energy storage device and the valve flap is positioned within a respective busbar cooling channel or in a coolant tube coupled to the respective busbar cooling channel.

8. The system of claim 1, wherein coolant in the cooling system is configured to flow through each respective busbar cooling channel in parallel.

9. The system of claim 1, wherein each respective busbar cooling channel is comprised of a plate overmolded on a respective busbar, the plate formed with a depression that, when overmolded, forms the respective busbar cooling channel.

10. The system of claim 9, further comprising one or more additional cooling channels positioned on top of one or more respective overmolded busbars.

11. The system of claim 10, wherein each battery cell includes a positive tab and a negative tab, such that the electric energy storage device includes a plurality of positive tabs arranged on a first side of the electric energy storage device and a plurality of negative tabs arranged on a second side of the electric energy storage device, wherein the plurality of overmolded busbars includes a first overmolded busbar positioned at a longitudinal center of the electric energy storage device on the first side of the electric energy storage device, a second overmolded busbar positioned at first longitudinal end of the electric energy storage device on the first side of the electric energy storage device, and a third overmolded busbar positioned at second longitudinal end of the electric energy storage device on the first side of the electric energy storage device, and wherein the one or more additional cooling channels includes a first cooling channel positioned on top of the first overmolded busbar, wherein the second and third overmolded busbars do not include an additional cooling channel positioned thereon.

12. A system, comprising:
an electric energy storage device comprising a plurality of battery cells;
a plurality of busbars coupled to the electric energy storage device, each busbar including a respective busbar cooling channel fluidly coupled to a cooling system including a heat exchanger, wherein coolant in the cooling system is configured to flow through each respective busbar cooling channel;
one or more actively-controlled valves configured to control flow of the coolant in the cooling system; and
a controller configured to adjust a position of the one or more actively-controlled valves based on a plurality of temperatures across the electric energy storage device.

13. The system of claim 12, further comprising a plurality of thermistors positioned across the electric energy storage device, and wherein the controller is configured to measure the plurality of temperatures based on output from the plurality of thermistors.

14. The system of claim 13, wherein the one or more actively-controlled valves includes a plurality of actively-controlled valves, each actively-controlled valve positioned to control the flow of the coolant through a respective busbar cooling channel.

15. The system of claim 14, wherein the plurality of temperatures includes a respective temperature of each busbar of the plurality of busbars and wherein the controller is configured to adjust a position of each actively-controlled valve independently based on a corresponding respective temperature.

16. The system of claim 12, wherein each busbar cooling channel is housed in an over-molding of a respective busbar and further comprising an additional cooling channel positioned on top of one of the over-moldings, and wherein the one or more actively-controlled valves includes an actively-controlled valve configured to control the flow of the coolant through the additional cooling channel.

17. A method, comprising:
measuring or inferring a plurality of temperatures across an electric energy storage device comprising a plurality of battery cells and a plurality of busbars coupled to the electric energy storage device, each busbar including a respective over-molding housing a respective busbar cooling channel fluidly coupled to a cooling system including a heat exchanger, and wherein one or more of the plurality of busbars further includes a respective additional cooling channel positioned adjacent a respective over-molding; and
differentially cooling the plurality of busbars based on the plurality of temperatures by flowing different amounts of coolant through one or more respective busbar cooling channels and/or by flowing coolant through one or more respective additional cooling channels.

18. The method of claim 17, wherein flowing different amounts of coolant through one or more respective busbar cooling channels comprises flowing coolant through some but not all of the one or more respective busbar cooling channels.

19. The method of claim 17, wherein flowing different amounts of coolant through one or more respective busbar cooling channels comprises controlling one or more actively-controlled valves of a plurality of actively-controlled valves, each actively-controlled valve of the plurality of actively-controlled valves positioned to control flow of coolant through a respective busbar cooling channel.

20. The method of claim 17, wherein differentially cooling the plurality of busbars based on the plurality of temperatures by flowing different amounts of coolant through one or more respective busbar cooling channels and/or by flowing coolant through one or more respective additional cooling channels comprises flowing coolant through each respective busbar cooling channel and flowing coolant through each respective additional cooling channel, where some but not all busbars of the plurality of busbars is positioned adjacent an additional cooling channel.
